(19) United States
(12) Patent Application Publication
(10) Pub. No.: US 2013/0094168 A1
(43) Pub. Date: Apr. 18, 2013

(54) WALL MOUNTING FOR ON-BOARD ENTERTAINMENT CONTROL UNITS

(71) Applicant: AIRBUS OPERATIONS GMBH, Hamburg (DE)

(72) Inventors: Hartwig JAEGER, Jork (DE); Klaus HANNA, Hamburg (DE); Martin JEAN-JACQUES, Hamburg (DE); Frank RADEKE, Hamburg (DE)

(73) Assignee: AIRBUS OPERATIONS GMBH, Hamburg (DE)

(21) Appl. No.: 13/660,096

(22) Filed: Oct. 25, 2012

Related U.S. Application Data
(63) Continuation of application No. 13/210,073, filed on Aug. 15, 2011, now abandoned.
Application No. 13/210,073 is a continuation of application No. PCT/EP2010/050736, filed on Jan. 22, 2010.
(60) Provisional application No. 61/152,362, filed on Feb. 13, 2009.

(30) Foreign Application Priority Data
Feb. 13, 2009 (DE) 10 2009 008 847.4

(51) Int. Cl. H05K 7/12; H05K 5/03

(52) U.S. Cl. 361/808; 361/807

(57) ABSTRACT

A standardized wall mounting is provided for mounting control units of system components in an aircraft cabin with a fastening unit and at least one plug unit. The fastening unit is designed for guiding the control unit during an installation movement of the control unit on the wall mounting. The plug unit is designed for producing a plug connection between the control unit and the wall mounting during the installation movement of the control unit on the wall mounting.

### CROSS-REFERENCE TO RELATED APPLICATION

This application is a continuation of U.S. application Ser. No. 13/210,073, filed Aug. 15, 2011. U.S. application Ser. No. 13/210,073 is a continuation of International Application No. PCT/EP2010/050736, filed Jan. 22, 2010, which was published under PCT Article 21(2) and claims priority to German Patent Application No. 10 2009 008 847.4 filed Feb. 13, 2009 and to U.S. Provisional Patent Application No. 61/152,362 filed Feb. 13, 2009. The entire disclosures of each of the above-referenced applications are incorporated herein by reference.

### TECHNICAL FIELD

The technical field relates to the installation and mounting of on-board (in-flight) entertainment control units in an aircraft. More specifically, the technical field relates to a standardized wall mounting for in-flight entertainment control units in an aircraft cabin. The technical field further pertains to a control unit for being installed on a wall mounting, a control system with a wall mounting and a control unit, an aircraft with a control system, as well as a method for fastening a control unit on a wall in an aircraft cabin.

### BACKGROUND

In-flight entertainment (In-flight Entertainment=IFE) control units such as, for example, so-called RCC units (Flush-Mounted Remote Control Center=RCC) can be fastened on a monument of an aircraft cabin by screwing said units into the threads of a base plate that, in turn, is fastened on the monument with the aid of screws. In this case, the RCC is delivered in the form of individual components that are successively screwed onto the base plate.

The RCC to be mounted is delivered in the form of various different individual components and fastened on the base plate with several screws. The plug connection for connecting the RCC to the aircraft cabin is separately plugged and screwed to the base plate. The cable routing within the monument after the installation is frequently undefined and realized individually. DE 102004012262A1 and US020070063101A1 describe a mounting for cabin elements in an aircraft with a holder.

At least one object may be seen in facilitating a reliable, improved and simple installation of in-flight entertainment control units in an aircraft cabin. In addition, other objects, desirable features and characteristics will become apparent from the subsequent summary and detailed description, and the appended claims, taken in conjunction with the accompanying drawings and this background.

### SUMMARY

A standardized wall mounting, a control unit for being installed on a wall mounting, a control system with a wall mounting and a control unit, an aircraft with a control system and a method for fastening a control unit on a wall in an aircraft cabin according to the characteristics described and claimed herein are disclosed.

According to one exemplary embodiment of the invention, a standardized wall mounting for control units of system components in an aircraft cabin with a fastening unit and at least one plug unit is proposed. The fastening unit is designed for guiding the control unit during an installation movement of the control unit on the wall mounting. The plug unit is designed for producing or providing a plug connection between the control unit and the wall mounting during the installation movement of the control unit on the wall mounting.

Such a standardized wall mounting makes it possible to guide a control unit or an RCC on a part by means of the fastening unit, for example centering hooks, and to perpendicularly push this control unit onto a plug unit that is realized in the form of a plug and arranged on the aircraft cabin. In this case, the plug can be plugged on and unplugged from, for example, a base plate without requiring any preparations, wherein the base plate is arranged on the aircraft cabin. The centering hooks are arranged on the base plate that may be realized in a U-shaped fashion.

Such a standardized wall mounting furthermore makes it possible to directly suspend the control unit or the RCC on the base plate by means of the hooks, wherein said control unit then merely needs to be fixed in an upward direction. This makes it possible to save a significant amount of time and effort, for example, in the final assembly line (Final Assembly Line=FAL) or in the aircraft, respectively. Furthermore, the control unit can be quickly exchanged in case a defect occurs or new system developments or expansions are implemented such that the system can be easily reconfigured or updated.

Such a standardized wall mounting furthermore makes it possible to fasten on the base plate various RCC models that merely feature the defined mountings for being installed on the hook and a thread for being screwed to the base plate on the rear side.

Such a standardized wall mounting furthermore represents a standard that can be specified because the position of the hooks, the thread in the base plate and the plug unit that is realized, for example, in the form of an RCC plug can be clearly specified and standardized. This makes it possible to provide a standardized solution for the installation of RCCs of different sizes, for example, in the context of new aircraft developments. Consequently, it is no longer necessary to fasten the RCC by means of screws that restrict the RCC size to one compatible model. On a larger RCC monitor that cannot be divided, for example, the threads for fastening the monitor furthermore do not have to be covered by crimped-over sides on the base plate that would represent an exclusion criterion with respect to the scaling. The covering of the control unit is realized with a cover frame that is installed on the control unit as described below.

Such a standardized wall mounting furthermore simplifies the cooperation between galley (Galley) and in-flight entertainment (IFE) suppliers. Due to the uniform standard and the fact that both suppliers are familiar with this uniform standard, both suppliers can manufacture their components without lengthy consultations. The components that are manufactured in accordance with the standard and to meet the tolerances therefore can exactly fit to and into one another. Development costs, for example, at the aircraft manufacturer and the supplier are eliminated. Furthermore, the unit costs can also be reduced if the same standard is always manufactured.

Such a standardized wall mounting furthermore makes it possible to achieve higher tolerance accuracies because the plug, as well as the thread for fastening the RCC, are accommodated on the base plate rather than individually arranged on the base plate that is fastened on a monument installed on an aircraft cabin by means of screws.

According to another exemplary embodiment of the invention, the plug unit is realized in the form of a plug or socket, wherein the socket is fastened on the base plate, and wherein the plug is either integrated on the control unit or inserted into the socket between the socket and the control unit in the form of a separate component during the installation of the control unit on the wall mounting.

According to another exemplary embodiment of the invention, the standardized wall mounting may feature two or more fastening units.

According to another exemplary embodiment of the invention, the wall mounting furthermore features a base plate, wherein the base plate is designed for installing the wall mounting on the aircraft cabin, and wherein the plug unit is mounted on the base plate.

According to another exemplary embodiment of the invention, the fastening unit can be installed on the base plate.

According to another exemplary embodiment of the invention, the wall mounting furthermore features a monument, wherein the monument is installed on the aircraft cabin, and wherein the base plate is designed for being fastened on the monument by means of screws.

According to another exemplary embodiment of the invention, the wall mounting also features at least one guide pin, wherein the plug unit is designed for positioning the plug unit by means of the guide pin.

In such a wall mounting with a plug unit that features at least one guide pin, the plug unit in the form of a plug does not require a screw connection and centers itself by means of the guide pin.

According to another exemplary embodiment of the invention, the plug unit is designed for being detachably installed on the base plate.

According to another exemplary embodiment of the invention, the wall mounting furthermore features at least one thread, wherein the thread is designed for fastening the control unit on the wall mounting.

According to another exemplary embodiment of the invention, the thread is arranged on the base plate.

According to another exemplary embodiment of the invention, the wall mounting furthermore features a cover frame, wherein the cover frame is designed [text missing] on the control unit by means of a snap-on connection in order to cover the control unit. The snap-on mechanism may be realized, for example, in the form of a spring-loaded snap fastener or any type of snap fastener.

According to another exemplary embodiment of the invention, the wall mounting furthermore features a frame, wherein the frame is realized such that it can be installed on the base plate by means of a snap-on connection (snap fastener), wherein the frame is designed for fastening the control unit, and wherein the frame is designed for aligning the control unit in a horizontal direction and a vertical direction after the installation movement of the control unit has been carried out.

According to another exemplary embodiment of the invention, the snap fastener is realized in the form of a spring-loaded snap fastener.

According to another exemplary embodiment of the invention, a control unit for system components in an aircraft cabin for being installed on a wall mounting of one of the preceding exemplary embodiments is proposed.

According to another exemplary embodiment, the control unit is designed for being fixed on the base plate underneath the monitor of the control unit by means of at least one screw.

According to another exemplary embodiment, the control unit can be fixed on a base plate underneath the monitor of the control unit by means of several screws.

According to another exemplary embodiment of the invention, a control system for controlling in-flight entertainment units in an aircraft cabin with a wall mounting of one of the preceding exemplary embodiments and a control unit of one of the preceding exemplary embodiments is proposed.

According to another exemplary embodiment, an aircraft with a control system of the preceding exemplary embodiment is proposed.

According to another exemplary embodiment of the invention, a method for fastening a control unit of system components on a wall in an aircraft cabin with the following steps is proposed, wherein the control unit is positioned in a first position relative to a wall mounting and the control unit is guided from the first position into a second position by a fastening unit of the wall mounting, and wherein a plug connection between the control unit and the wall mounting is produced and the control unit is fixed due to the movement of the control unit from the first position into the second position.

According to another exemplary embodiment of the invention, the method for fastening a control unit of system components on a wall in an aircraft cabin furthermore comprises the fastening of the control unit on the wall mounting by installing a frame on the wall mounting.

The individual characteristics of the different exemplary embodiments naturally can also be combined among one another such that advantageous effects that exceed the sum of the individual effects also may be achieved in some instances, namely even if they are not expressly described herein.

It should be noted, in particular, that the characteristics with respect to the standardized wall mounting that are described above and below can also be implemented in the method, the aircraft, the control system and the control unit and vice versa.

In addition, according to another exemplary embodiment, a system for mounting in-flight entertainment units in an aircraft cabin is provided. The system can include a control unit of system components, and a wall mounting for mounting the control unit in the aircraft cabin. The wall mounting includes a fastening unit that is a centering hook that is designed for guiding the control unit during an installation movement of the control unit on the wall mounting. The wall mounting also includes at least one plug unit that produces a plug connection between the control unit and the wall mounting during the installation movement of the control unit on the wall mounting.

Also provided is a system that further comprises a base plate that couples the wall mounting to the monument installed on the aircraft cabin, and the at least one plug unit is mounted on the base plate. In addition, provided is a system, in which the fastening unit is mounted to the base plate. Also provided is a system, in which the at least one plug unit includes a guide pin. Further provided herein is a system, in which the at least one plug unit is detachably coupled to the base plate, and a system that comprises at least one thread for receipt of a screw to fasten the control unit on the base plate. In addition, provided is a system, in which the at least one thread is arranged on the base plate. Also provided is a system that comprises a cover frame that snaps onto the control unit to cover the control unit, and a system that comprises a frame that snaps onto the base plate for aligning the control unit relative to the base plate. Also provided is a system in which the frame aligns the control unit in a horizontal direction and a vertical direction after the installation movement of the control unit has been carried out.

Further provided is a system for mounting in-flight entertainment units in an aircraft cabin. The system can include a control unit having a hook eye and a plug, and a base plate fixedly mounted to a monument installed on an aircraft cabin. The base plate includes a fastening unit having a centering hook that engages the hook eye of the control unit and guides the control unit during the coupling of the control unit to the base plate. The base plate also includes at least one plug unit that receives the plug of the control unit to produce a plug connection between the control unit and the base plate during the coupling of the control unit to the base plate. The at least one plug unit includes a guide pin.

Also provided is a system in which the at least one plug unit is detachably mountable to the base plate. Further provided is a system that comprises at least one thread for receipt of a screw to fasten the control unit on the base plate. The at least one thread can be arranged on the base plate. Also provided is a system that comprises a cover frame that snaps onto the control unit to cover the control unit, and a frame that snaps onto the base plate and aligns the control unit relative to the base plate. The frame aligns the control unit in a horizontal direction and a vertical direction after the coupling of the control unit to the base plate.

According to another exemplary embodiment, a system for mounting in-flight entertainment units in an aircraft cabin is provided. The system can include a control unit having a monitor on a first side, and a hook eye and a plug on a second side. The system can include a base plate fixedly mounted to a monument installed on an aircraft cabin. The base plate includes a fastening unit having a centering hook that engages the hook eye of the control unit and guides the control unit during the coupling of the control unit to the base plate. The base plate includes at least one plug unit that receives the plug of the control unit to produce a plug connection between the control unit and the base plate during the coupling of the control unit to the base plate. The at least one plug unit includes a guide pin. The system further includes a frame that snaps onto the base plate and aligns the control unit in a horizontal direction and a vertical direction after the coupling of the control unit to the base plate. The base plate can be U-shaped.

Further provided is a wall mounting for mounting a control unit of in-flight entertainment units in an aircraft cabin. The wall mounting includes a fastening unit that is a centering hook that is designed for guiding the control unit during an installation movement of the control unit relative to the wall mounting. The wall mounting also includes at least one plug unit that produces a plug connection between the control unit and the wall mounting during the installation movement of the control unit. The wall mounting further includes a base plate that couples the wall mounting to a monument installed on the aircraft cabin, and the at least one plug unit is mounted on the base plate.

In addition, provided is a wall mounting, in which the fastening unit is mounted to the base plate. Also provided is a wall mounting, in which the at least one plug unit includes a guide pin. Further provided herein is a wall mounting, in which the at least one plug unit is detachably coupled to the base plate, and a wall mounting that comprises at least one thread for receipt of a screw to fasten the control unit on the base plate. In addition, provided is a wall mounting, in which the at least one thread is arranged on the base plate. Also provided is a wall mounting that comprises a cover frame that snaps onto the control unit to cover the control unit, and a wall mounting that comprises a frame that snaps onto the base plate for aligning the control unit relative to the base plate. Also provided is a wall mounting in which the frame aligns the control unit in a horizontal direction and a vertical direction after the installation movement of the control unit has been carried out.

According to various teachings of the present disclosure, provided is a wall mounting for mounting a control unit of in-flight entertainment units in an aircraft cabin. The wall mounting comprises a control unit having a hook eye and a plug, and a base plate fixedly mounted to a monument installed on an aircraft cabin. The base plate includes a fastening unit having a centering hook that engages the hook eye of the control unit and guides the control unit during the coupling of the control unit to the base plate, and at least one plug unit that receives the plug of the control unit to produce a plug connection between the control unit and the base plate during the coupling of the control unit to the base plate. The at least one plug unit includes a guide pin.

Also provided is a wall mounting in which the at least one plug unit is detachably mountable to the base plate. Further provided is a wall mounting that comprises at least one thread for receipt of a screw to fasten the control unit on the base plate. The at least one thread can be arranged on the base plate. Also provided is a wall mounting that comprises a cover frame that snaps onto the control unit to cover the control unit, and a frame that snaps onto the base plate and aligns the control unit relative to the base plate. The frame aligns the control unit in a horizontal direction and a vertical direction after the coupling of the control unit to the base plate.

According to various exemplary embodiments, provided is a wall mounting for mounting a control unit of in-flight entertainment units in an aircraft cabin. The wall mounting includes a control unit having a monitor on a first side, and a hook eye and a plug on a second side. The wall mounting also includes a base plate fixedly mounted to a monument installed on an aircraft cabin. The base plate includes a fastening unit having a centering hook that engages the hook eye of the control unit and guides the control unit during the coupling of the control unit to the base plate, and at least one plug unit that receives the plug of the control unit to produce a plug connection between the control unit and the base plate during the coupling of the control unit to the base plate. The at least one plug unit includes a guide pin. The wall mounting also includes a frame that snaps onto the base plate and aligns the control unit in a horizontal direction and a vertical direction after the coupling of the control unit to the base plate. The base plate can be U-shaped.

A person skilled in the art can gather other characteristics and advantages of the disclosure from the following description of exemplary embodiments that refers to the attached drawings, wherein the described exemplary embodiments should not be interpreted in a restrictive sense.

### BRIEF DESCRIPTION OF THE DRAWINGS

The various embodiments will hereinafter be described in conjunction with the following drawing figures, wherein like numerals denote like elements, and wherein:

FIG. 1a shows a schematic representation of a control system for controlling in-flight entertainment units in an aircraft cabin with a standardized wall mounting and a control unit according to an exemplary embodiment of the invention;

FIG. 1b shows another schematic representation of the control system of FIG. 1a;

FIG. 1c shows a schematic lateral section through the control system of FIG. 1a;

FIG. 2a shows a schematic perspective representation of a control system for controlling in-flight entertainment units in an aircraft cabin with a standardized wall mounting and a control unit according to an exemplary embodiment of the invention;

FIG. 2b shows a schematic front view of the control system of FIG. 2a; and

FIG. 3a shows a perspective representation of a standardized wall mounting according to an exemplary embodiment of the invention;

FIG. 3b shows a schematic top view of the standardized wall mounting of FIG. 3a;

FIG. 3c shows a schematic lateral section through the standardized wall mounting of FIG. 3a;

FIG. 3d shows a schematic horizontal section through the standardized wall mounting of FIG. 3a;

FIG. 4a shows a schematic perspective representation of a cover frame according to an exemplary embodiment of the invention;

FIG. 4b shows a schematic top view of the cover frame of FIG. 4a;

FIG. 4c shows a schematic lateral section through the cover frame of FIG. 4a;

FIG. 4d shows a schematic horizontal section through the cover frame of FIG. 4a;

FIG. 5a shows a schematic perspective representation of a control system for controlling in-flight entertainment units in an aircraft cabin with a standardized wall mounting and a control unit according to an exemplary embodiment of the invention;

FIG. 5b shows a schematic top view of the control system of FIG. 5a;

FIG. 5c shows a schematic lateral section through the standardized wall mounting of FIG. 5b along the line of section A-A in FIG. 5b;

FIG. 5d shows a schematic lateral section through the frame for fastening the control unit of FIG. 5b;

FIG. 6a shows another schematic top view of the standardized wall mounting of FIG. 5b;

FIG. 6b shows a schematic lateral section through the standardized wall mounting of FIG. 6a;

FIG. 7a shows a schematic top view of a control system for controlling in-flight entertainment units in an aircraft cabin with a standardized wall mounting and a control unit according to an exemplary embodiment of the invention;

FIG. 7b shows a lateral section through the frame for fastening the control unit of FIG. 7a;

FIG. 7c shows a lateral section through a frame for fastening the control unit of FIG. 7a along the line of section B-B in FIG. 7a;

FIG. 8 shows a schematic representation of an aircraft with a control system according to an exemplary embodiment of the invention; and

FIG. 9 shows a flow chart of a method for fastening a control unit of system components on a wall in an aircraft cabin according to an exemplary embodiment of the invention.

### DETAILED DESCRIPTION

Exemplary embodiments of the invention are described below with reference to the attached drawings. The figures show schematic illustrations that are not drawn true-to-scale. In the following description of the figures, identical or similar elements are identified by the same reference symbols.

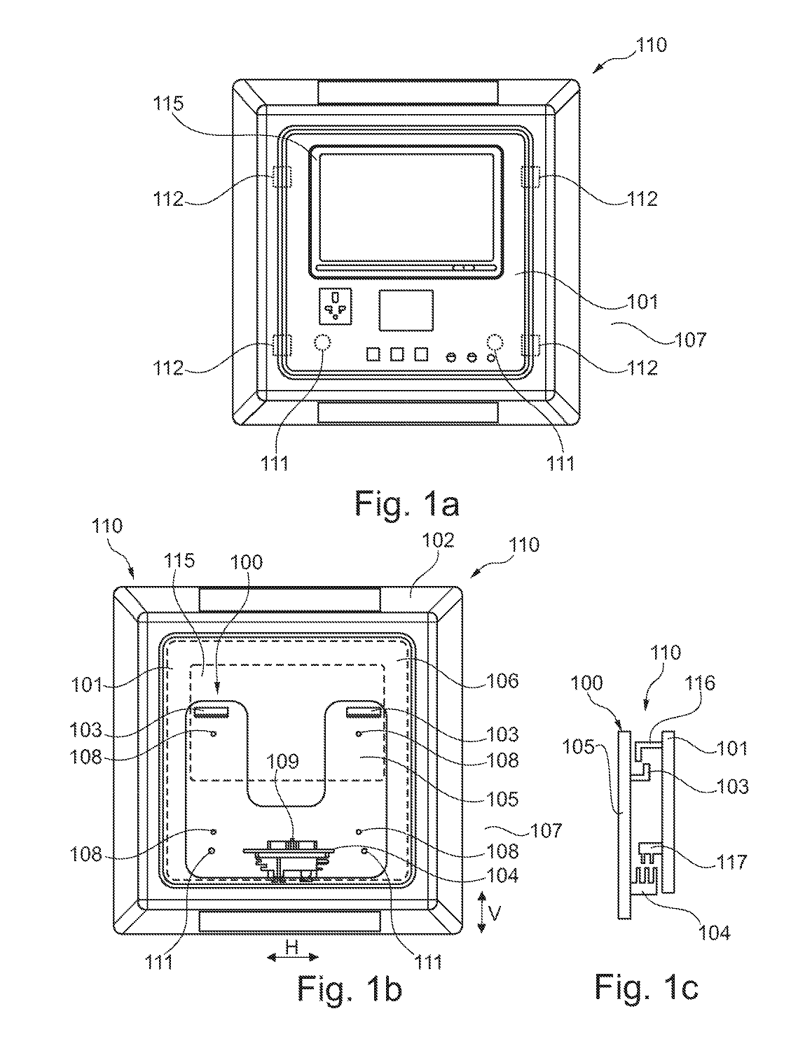

FIG. 1a shows a control system 110 for controlling in-flight entertainment units in an aircraft cabin 107 with a control unit 101 that is fastened on a base plate 105 (see FIG. 1b) by means of two threads 111 and screws. A cover frame 102 can be clipped onto the control unit 101 by means of a clip-on mechanism 112. The control unit 101 features a monitor 115.

FIG. 1b shows the control system 110 with a wall mounting 100. The control unit 101 with the monitor 115 is illustrated with broken lines. The standardized wall mounting 100 is realized in the form of a U-shaped base plate 105 with two fastening units 103. The base plate 105 furthermore features several threads 108 for fastening the base plate 105, for example, on the wall of an aircraft cabin 107.

A plug unit 104 is mounted perpendicular to the base plate 105 and is positioned and/or centered with the help of a guiding pin 109.

The base plate 105 furthermore features two threads 111 for fastening the control unit 101 on the base plate 105 by means of screws.

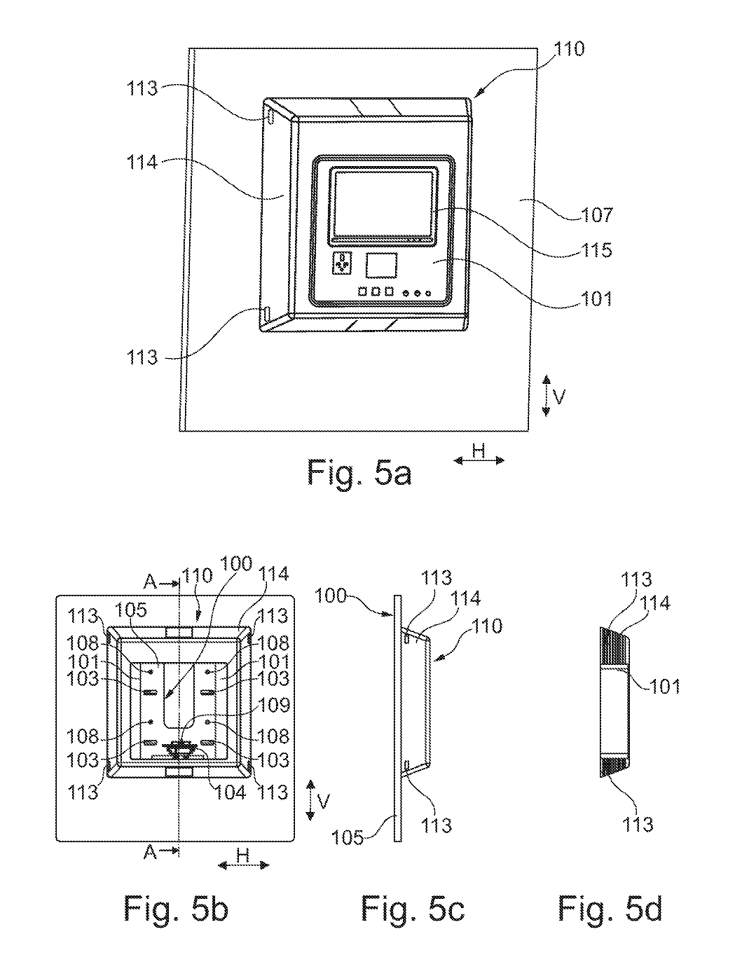

FIG. 1b furthermore shows a cover frame 102 for covering the control unit 101. The cover frame 102 can also be realized in the form of a frame 114 (see FIG. 5a to FIG. 7c) that can be installed on the base plate 105 by means of a snap fastener 113 (see FIG. 5a to FIG. 7c) and is designed for fastening the control unit 101, wherein the frame 114 is designed for aligning the control unit 101 in a horizontal direction H and a vertical direction V as illustrated in FIG. 1b.

A monument 106 is installed on the aircraft cabin 107, wherein the base plate 105 can be fastened on the monument 106 by means of screws that engage into the threads 108 of the base plate 105.

FIG. 1c shows a lateral section through the control system 110 of FIG. 1a with a standardized wall mounting 100 that is realized in the form of a base plate 105 and features fastening units 103 that are realized in the form of hooks, as well as a plug unit 104 that is realized in the form of a socket. The control system 110 furthermore features a control unit 101 with a plug 117 and a hook eye 116. The hook eye 116 is designed for being received on the fastening unit 103 of the wall mounting 100. The plug 117 installed on the control unit 101 fits into the socket of the wall mounting 100.

During the installation of the control unit 101 on the wall mounting 100, the eyes 116 of the control unit 101 are guided through fastening units 103 of the wall mounting 100, wherein the plug 117 of the control unit 101 is simultaneously inserted or plugged into the plug unit 104 in the form of a socket of the wall mounting 100 in the form of a base plate 105.

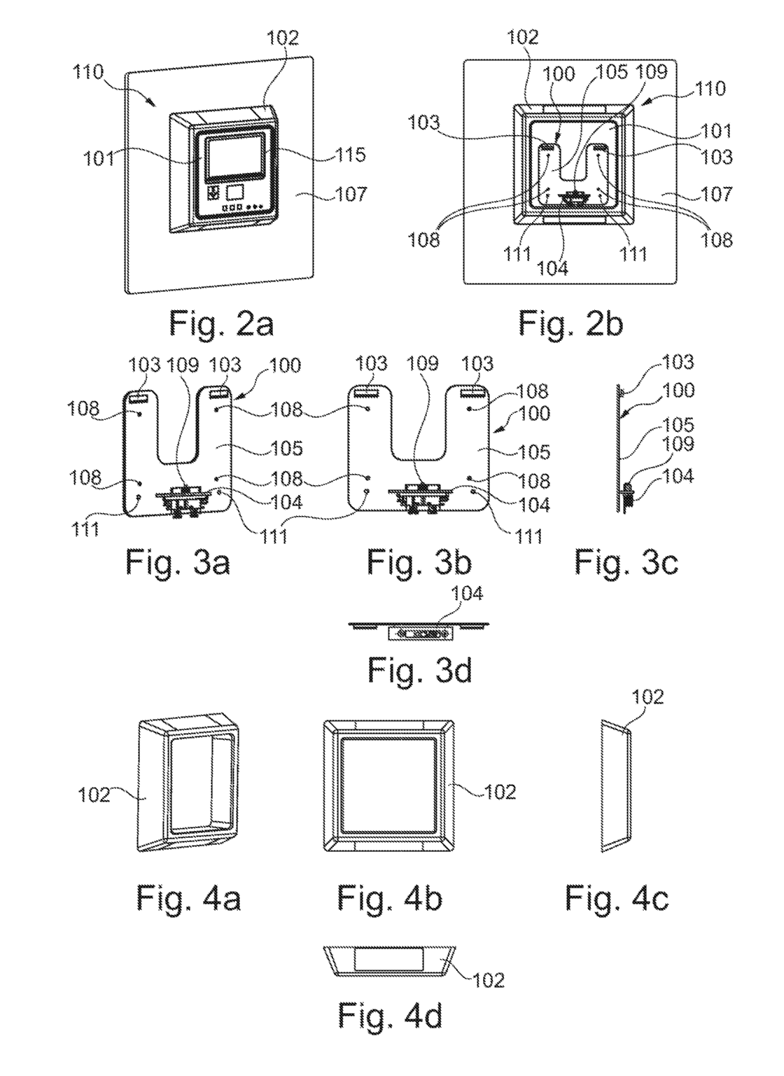

FIG. 2a shows a perspective representation of a control system 110 of FIG. 1a with a cover frame 102 for covering a control unit 101 that features a monitor 115. The control system 110 is arranged in an aircraft cabin 107.

FIG. 2b shows a top view of the control system 110 of FIG. 2a with a cover frame 102 for covering the control unit 101 and a standardized wall mounting 100 with two hooks 103 or fastening units 103, respectively, for guiding the control unit 101 during the installation of the control unit 101 on the wall mounting 100. FIG. 2b also shows a plug unit 104 that is installed on a base plate 105 and designed for producing a plug connection between the control unit 101 and the wall mounting 100 during the installation of the control unit 101 on the wall mounting 100.

FIG. 2b furthermore shows a guide pin 109, wherein the plug unit 104 is designed for positioning the plug unit 104 by means of the guide pin 109.

The threads 108 are designed for fastening the base plate 105 on the aircraft cabin 107 by means of screws. The standardized wall mounting 100 furthermore features two threads 111, wherein the threads 111 are designed for fastening the control unit 101 on the wall mounting 100 in the form of a base plate 105.

FIG. 3a shows a perspective representation of the standardized wall mounting 100 of FIG. 2b with the elements of the wall mounting 100 described with reference to FIG. 2b.

FIG. 3b shows a top view of the wall mounting 100 of FIG. 3a with all elements of the wall mounting 100 described with reference to FIG. 3a.

FIG. 3c shows a lateral section through the standardized wall mounting 100 with a fastening unit 103 that may be realized in the form of hooks, as well as a guide pin 109 for positioning a plug unit 104.

FIG. 3d shows a schematic horizontal section through the wall mounting with a plug unit 104.

FIG. 4a shows a schematic perspective representation of a cover frame 102 for covering a (not-shown) control unit by being clipped thereon.

FIG. 4b shows a top view of the cover frame 102 of FIG. 4a.

FIG. 4c shows a lateral section through the cover frame 102 of FIG. 4b.

FIG. 4d shows a lateral top view of the cover frame 102 of FIG. 4b.

FIG. 5a shows a perspective representation of a control system 110 for controlling in-flight entertainment units in an aircraft cabin 107 with a control unit 101 that is fixed in all directions on a wall of an aircraft cabin 107 by means of a frame 114 that is clipped onto a (not-shown) base plate 105 by means of spring-loaded snap fasteners 113. The control unit 101 features a monitor 115.

FIG. 5b shows a schematic top view of the control system 110 of FIG. 5a with a control unit 101 that is guided by fastening units 103, e.g., in the form of hooks during the installation of the control unit 101 on the standardized wall mounting 100 and fastened by means of a plug connection between the control unit 101 and the wall mounting 100 during the installation of the control unit 101 on the standardized wall mounting 100.

FIG. 5b also shows a guide pin 109 that positions or centers the plug unit 104. The standardized wall mounting 100 is realized in the form of a U-shaped base plate 105 that features threads 108 designed for fastening the base plate on an aircraft cabin 107 or a monument fastened on an aircraft cabin 107 with the aid of screws.

FIG. 5b furthermore shows a frame 114 that is designed for being installed on the base plate 105 by means of several snap fasteners 113, wherein the frame 114 fastens and aligns the control unit 101 in a horizontal direction H and a vertical direction V.

FIG. 5c shows a lateral section through the control system 110 of FIG. 5b with a wall mounting 100 that is realized in the form of a base plate 105 and onto which a frame 114 is clipped with the aid of snap fasteners 113.

FIG. 5d shows a lateral section through the frame 113 for fastening the control unit 110 with the aid of snap fasteners 113, as well as the control unit 101, along the line of section A-A in FIG. 5b.

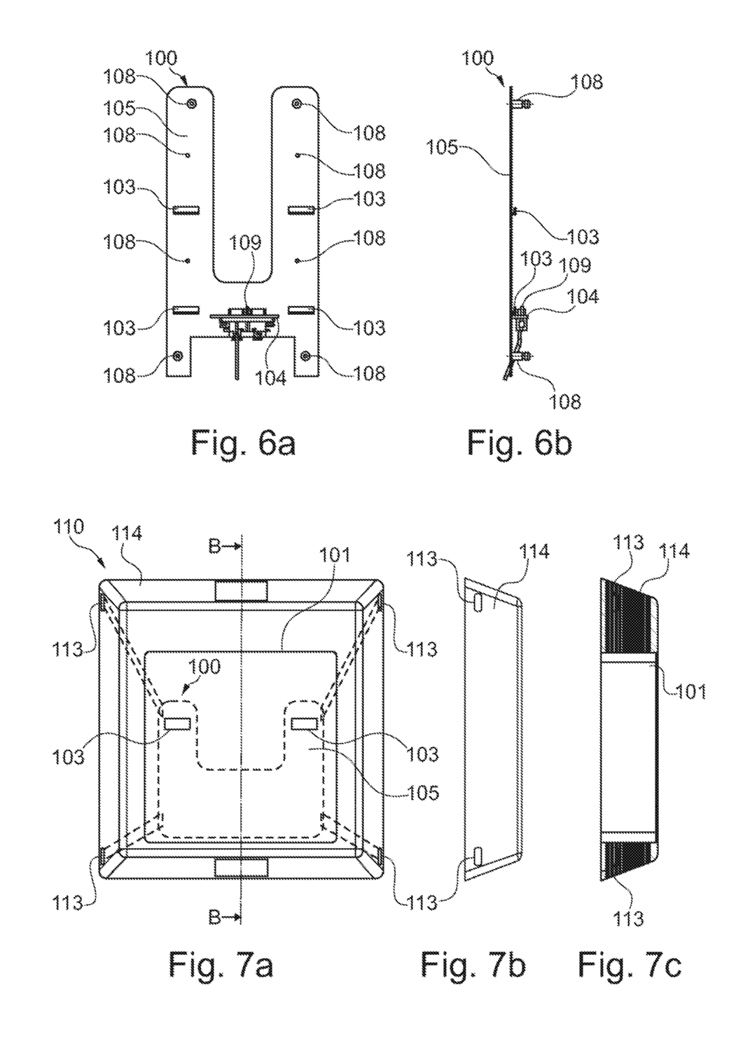

FIG. 6a shows a standardized wall mounting 100 with all elements of the exemplary embodiment illustrated in FIG. 5b.

FIG. 6b shows a lateral section through the wall mounting 100 of FIG. 6a with fastening units 103 that are realized in the form of hooks, as well as screws 108 that are designed for fastening the wall mounting 100 in the form of a base plate 105 on an aircraft cabin 107. This figure furthermore shows a plug unit 104 that is installed on the base plate 105 and positioned on the base plate 105 by means of a guide pin 109.

FIG. 7a shows a control system 110 for controlling in-flight entertainment units in an aircraft cabin 107 with a wall mounting 108 and a control unit 101. Fastening units 103 are realized in the form of hooks and designed for guiding the control unit 101 during the installation of the control unit 101 on the wall mounting 100. Although a plug unit 104 for producing a plug connection between the control unit 101 and the wall mounting 100 during the installation of the control unit 101 on the wall mounting 100 is not illustrated in this figure, it is assumed that the control system 110 shown also contains such a plug unit.

A frame 114 can be installed on the standardized wall mounting 100 in the form of a base plate 105 by means of snap fasteners 103. The frame 114 serves for fastening the control unit 101.

FIG. 7b shows a lateral section through the frame 114 for fastening the control unit 101 by means of snap fasteners 113 that make it possible to install the frame 114 on the base plate 105 as illustrated in FIG. 7a.

FIG. 7c shows a lateral section through the frame 114 with snap fasteners 103 and a control unit 101 along the line of section B-B in FIG. 7a.

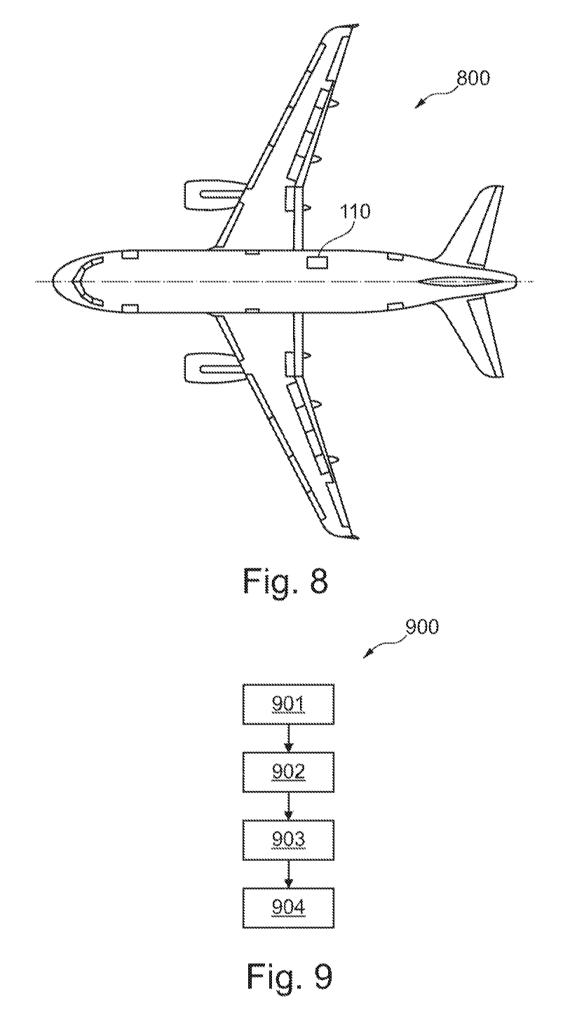

FIG. 8 shows a schematic representation of an aircraft 800 with a control system 110.

FIG. 9 shows a flow chart of a method 900 for fastening a control unit 101 of system components in an aircraft cabin 107 on a wall.

The method 900 features the following steps: in step 901, the control unit 101 is positioned in a first position relative to a wall mounting. In step 902, the control unit 101 is guided from the first position into a second position by a fastening unit 103 of the wall mounting 100. In another step 903, a plug connection between the control unit 101 and the wall mounting 100 is produced and the control unit 101 is fixed due to the movement of the control unit 101 from the first position into the second position. In the final step 904, the control unit 101 is fastened on the wall mounting 100 by installing a frame 114 on the wall mounting 100.

Although the invention was described with reference to exemplary embodiments, it is possible to realize various changes and modifications without deviating from the protective scope of the invention. The standardized wall mounting according to the invention can be used for installing any control units of transport means such as vehicles, aircraft, helicopters, and watercraft or rail vehicles on the wall mounting.

As a supplement, it should be noted that “comprising” or “featuring” does not exclude any other elements or steps, and that “a” or “an” does not exclude a plurality. For example, the standardized wall mounting therefore may feature, in particular, more than one fastening unit, more than one plug unit, more than one base plate, more than one guide pin, more than one thread, more than one cover frame and more than one frame.

It should furthermore be noted that characteristics or steps that were described with reference to one of the above exemplary embodiments may also be used in combination with other characteristics or steps of other above-described exemplary embodiments. The reference symbols in the claims should not be interpreted in a restrictive sense.

Moreover, while at least one exemplary embodiment has been presented in the foregoing summary and detailed description, it should be appreciated that a vast number of variations exist. It should also be appreciated that the exemplary embodiment or exemplary embodiments are only examples, and are not intended to limit the scope, applicability, or configuration in any way. Rather, the foregoing summary and detailed description will provide those skilled in the art with a convenient road map for implementing an exemplary embodiment, it being understood that various changes may be made in the function and arrangement of elements described in an exemplary embodiment without departing from the scope as set forth in the appended claims and their legal equivalents.

What is claimed is:

1. A control system for controlling in-flight entertainment units in an aircraft cabin, comprising:
a control unit of system components; and
a wall mounting for mounting the control unit in the aircraft cabin, including:
a fastening unit that is a centering hook that is designed for guiding the control unit during an installation movement of the control unit on the wall mounting; and
at least one plug unit that produces a plug connection between the control unit and the wall mounting during the installation movement of the control unit on the wall mounting.

2. The system of claim 1, wherein the wall mounting further comprises:
a base plate that couples the wall mounting to a monument installed on the aircraft cabin,
wherein the at least one plug unit is mounted on the base plate.

3. The system of claim 2, wherein the fastening unit is mounted to the base plate.

4. The system of claim 1, wherein the at least one plug unit includes a guide pin.

5. The system of claim 2, wherein the at least one plug unit is detachably coupled to the base plate.

6. The system of claim 2, further comprising:
at least one thread for receipt of a screw to fasten the control unit on the base plate.

7. The system of claim 6, wherein the at least one thread is arranged on the base plate.

8. The system of claim 1, further comprising:
a cover frame that snaps onto the control unit to cover the control unit.

9. The system of claim 2, further comprising:
a frame that snaps onto the base plate for aligning the control unit relative to the base plate.

10. The system of claim 9, wherein the frame aligns the control unit in a horizontal direction and a vertical direction after the installation movement of the control unit has been carried out.

11. A control system for controlling in-flight entertainment units in an aircraft cabin, comprising:
a control unit having a hook eye and a plug;
a base plate fixedly mounted to a monument installed on an aircraft cabin, the base plate including:
a fastening unit having a centering hook that engages the hook eye of the control unit and guides the control unit during the coupling of the control unit to the base plate; and
at least one plug unit that receives the plug of the control unit to produce a plug connection between the control unit and the base plate during the coupling of the control unit to the base plate,
wherein the at least one plug unit includes a guide pin.

12. The system of claim 11, wherein the at least one plug unit is detachably mountable to the base plate.

13. The system of claim 12, further comprising:
at least one thread for receipt of a screw to fasten the control unit on the base plate.

14. The system of claim 13, wherein the at least one thread is arranged on the base plate.

15. The system of claim 11, further comprising:
a cover frame that snaps onto the control unit to cover the control unit.

16. The system of claim 11, further comprising:
a frame that snaps onto the base plate and aligns the control unit relative to the base plate.

17. The system of claim 16, wherein the frame aligns the control unit in a horizontal direction and a vertical direction after the coupling of the control unit to the base plate.

18. A control system for controlling in-flight entertainment units in an aircraft cabin, comprising:
a control unit having a monitor on a first side, and a hook eye and a plug on a second side;
a base plate fixedly mounted to a monument installed on an aircraft cabin, the base plate including:
a fastening unit having a centering hook that engages the hook eye of the control unit and guides the control unit during the coupling of the control unit to the base plate;
at least one plug unit that receives the plug of the control unit to produce a plug connection between the control unit and the base plate during the coupling of the control unit to the base plate,
wherein the at least one plug unit includes a guide pin; and
a frame that snaps onto the base plate and aligns the control unit in a horizontal direction and a vertical direction after the coupling of the control unit to the base plate.

19. The system of claim 18, wherein the base plate is U-shaped.
